(19) United States
(12) Patent Application Publication
(10) Pub. No.: US 2026/0011685 A1
(43) Pub. Date: Jan. 8, 2026

(54) SEMICONDUCTOR DEVICE

(71) Applicant: Mitsubishi Electric Corporation, Tokyo (JP)

(72) Inventors: Yoshimasa TAKAKU, Tokyo (JP); Keisuke TADA, Tokyo (JP); Satoru KOZUKA, Tokyo (JP)

(73) Assignee: Mitsubishi Electric Corporation, Tokyo (JP)

(21) Appl. No.: 19/117,409

(22) PCT Filed: Jun. 14, 2023
(86) PCT No.: PCT/JP2023/022085

§ 371 Date: Apr. 1, 2025

(51) Int. Cl. H01L 25/03; H01L 23/00; H01L 23/31; H01L 23/40; H01L 23/498; H01L 23/538; H01L 25/07

(52) U.S. Cl. CPC H01L 25/03; H01L 23/3121; H01L 23/4006; H01L 23/49811; H01L 23/5385; H01L 25/072; H01L 2023/405; H01L 24/48; H01L 2224/48137; H01L 2224/48225; H01L 2924/1203; H01L 2924/13055

(57) ABSTRACT

A semiconductor device includes a plurality of semiconductor modules. Each of the plurality of semiconductor modules includes: a base plate having a first surface and a second surface, the first surface being exposed to the outside of the semiconductor module, the second surface being on a side opposite to the first surface; an insulated substrate with a circuit pattern provided thereon; a semiconductor chip bonded to the circuit pattern; a sealer that seals the insulated substrate and the semiconductor chip; and a first main electrode and a second main electrode drawn out of the sealer in a direction opposite to a direction from the sealer toward the base plate. The semiconductor module has a planar shape with four corners, and has a rotationally symmetric shape.

### FIELD

The present disclosure relates to a semiconductor device including a semiconductor element for power control.

### BACKGROUND

Conventionally, a designer who designs an electric apparatus such as an industrial apparatus or a consumer apparatus often designs the electric apparatus by selecting a power module from among several power modules provided by a manufacturer that manufactures a semiconductor device for power control. The power module is a semiconductor device including a plurality of semiconductor chips mounted in a single package. When a power module is selected from among power modules provided by a manufacturer, a circuit layout, the shape of a cooler, or the like is determined by the selected power module. Therefore, the outer shape of the electric apparatus is limited to some extent. Meanwhile, there is also a demand for an increase in the degree of freedom of the shape of the electric apparatus. However, it is also difficult to redesign a power module for each electric apparatus from the viewpoint of the manufacturing cost of the power module or the reliability of the power module.

Patent Literature 1 discloses a semiconductor device in which a plurality of semiconductor chips are disposed in separate semiconductor modules configured independently of each other, and the semiconductor modules are connected to each other, so that a function equivalent to that of a power module can be implemented. Each semiconductor module of the semiconductor device disclosed in Patent Literature 1 has the same configuration. Each of a collector main electrode and an emitter main electrode included in a semiconductor module is disposed in such a way as to reach an upper surface of the semiconductor module, and is connectable to an external circuit and a semiconductor module adjacent to the semiconductor module. For example, semiconductor modules adjacent to each other are disposed such that a collector main electrode of one of the semiconductor modules and an emitter main electrode of the other semiconductor module face each other, and each of the collector main electrode and the emitter main electrode is fixed to a conductive plate with a bolt. As a result, the collector main electrode and the emitter main electrode are connected to each other, and the two semiconductor modules are fixed to each other.

### CITATION LIST

### Patent Literature

Patent Literature 1: WO 2014/030254 A

### SUMMARY OF INVENTION

### Problem to be Solved by the Invention

In each semiconductor module of the semiconductor device disclosed in Patent Literature 1, two collector main electrodes are adjacent to each other, and two emitter electrodes are adjacent to each other. For example, when semiconductor modules adjacent to each other are disposed such that a collector main electrode of one of the semiconductor modules faces an emitter main electrode of the other semiconductor module, a main electrode of the one of the semiconductor modules located in such a way as to be connectable to the external circuit may be limited to an emitter electrode, and a main electrode of the other semiconductor module located in such a way as to be connectable to the external circuit may be limited to a collector electrode. That is, the semiconductor device disclosed in Patent Literature 1 has a problem in that when the way of connection between the semiconductor modules is determined, arrangement of the semiconductor modules is inevitably determined, leading to a decrease in the degree of freedom in the arrangement of the semiconductor modules. In the case of the semiconductor device disclosed in Patent Literature 1, it is difficult to change the arrangement of the semiconductor modules in such a way as to be suitable for connection with an external circuit, so that there are cases where it is necessary to take measures such as carrying out wiring so as to connect the main electrode of each semiconductor module to the external circuit.

The present disclosure has been made in view of the above, and an object of the present disclosure is to obtain a semiconductor device in which each of a plurality of semiconductor modules can be disposed with a high degree of freedom.

### Means to Solve the Problem

In order to solve the above-described problem and achieve the object, a semiconductor device according to the present disclosure includes a plurality of semiconductor modules. Each of the plurality of semiconductor modules includes: a base plate having a first surface and a second surface, the first surface being exposed to the outside of the semiconductor module, the second surface being on a side opposite to the first surface; an insulated substrate disposed on a second surface side, a circuit pattern being provided on the insulated substrate; a semiconductor chip bonded to the circuit pattern; a sealer provided on the side of second surface, the sealer sealing the insulated substrate and the semiconductor chip; and a first main electrode and a second main electrode drawn out of the sealer in a direction opposite to the base plate. When viewed from a normal direction of the second surface, the semiconductor module has a planar shape with four corners, and has a rotationally symmetric shape. At each of a first corner and a second corner, the first main electrode is drawn out of the sealer, the first corner and the second corner being two of the four corners, the first corner and the second corner facing each other across a center of the planar shape. At each of a third corner and a fourth corner, the second main electrode is drawn out of the sealer, the third corner and the fourth corner being two of the four corners other than the first corner and the second corner.

### Effects of the Invention

The semiconductor device according to the present disclosure has the effect of enabling each of a plurality of semiconductor modules to be disposed with a high degree of freedom.

### BRIEF DESCRIPTION OF DRAWINGS

FIG. 1 is an exploded perspective view of a semiconductor device according to a first embodiment, which illustrates an exemplary configuration of the semiconductor device.

FIG. 2 is a perspective view of a semiconductor module included in the semiconductor device according to the first embodiment.

FIG. 3 is a top view of the semiconductor module included in the semiconductor device according to the first embodiment.

FIG. 4 is a side view of the semiconductor module included in the semiconductor device according to the first embodiment.

FIG. 5 is a bottom view of the semiconductor module included in the semiconductor device according to the first embodiment.

FIG. 6 is a longitudinal sectional view of the semiconductor module included in the semiconductor device according to the first embodiment.

FIG. 7 is a transverse sectional view of the semiconductor module included in the semiconductor device according to the first embodiment. FIG. 8 is an internal connection diagram of the semiconductor module included in the semiconductor device according to the first embodiment. FIG. 9 is a perspective view of the semiconductor device according to the first embodiment, which illustrates a state in which the semiconductor device is mounted on a substrate.

FIG. 10 is a plan view of the substrate on which the semiconductor device according to the first embodiment is mounted.

FIG. 11 is a diagram illustrating a first exemplary pattern of combination of the semiconductor modules in the first embodiment.

FIG. 12 is a diagram illustrating a second exemplary pattern of combination of the semiconductor modules in the first embodiment.

FIG. 13 is a perspective view of a semiconductor device according to a first modification of the first embodiment.

FIG. 14 is a top view of the semiconductor device according to the first modification of the first embodiment.

FIG. 15 is a perspective view of a semiconductor device according to a second modification of the first embodiment.

FIG. 16 is a top view of the semiconductor device according to the second modification of the first embodiment.

FIG. 17 is a perspective view of a semiconductor device according to a third modification of the first embodiment.

FIG. 18 is a perspective view of a semiconductor device according to a fourth modification of the first embodiment.

FIG. 19 is a perspective view of a semiconductor device according to a fifth modification of the first embodiment.

### DESCRIPTION OF EMBODIMENTS

Hereinafter, a semiconductor device according to an embodiment will be described in detail with reference to the drawings.

### First Embodiment

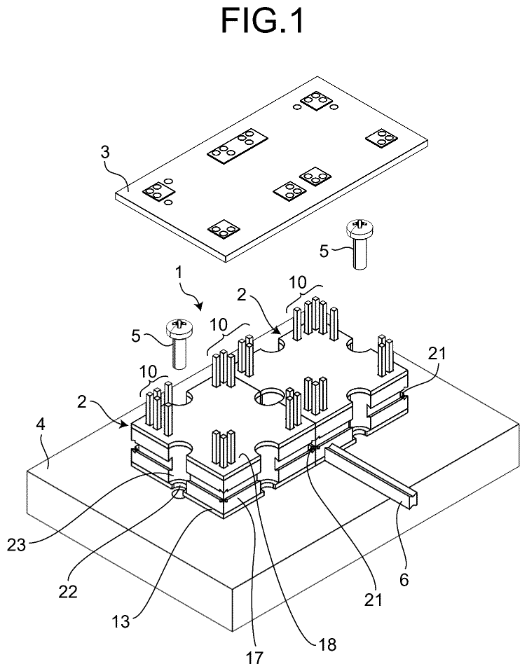

FIG. 1 is an exploded perspective view of a semiconductor device 1 according to a first embodiment, which illustrates an exemplary configuration of the semiconductor device 1. The semiconductor device 1 according to the first embodiment includes a plurality of semiconductor modules 2. The semiconductor device 1 is an integrated module in which the plurality of semiconductor modules 2 is integrated. Each of the plurality of semiconductor modules 2 has the same configuration. The semiconductor device 1 exemplified in FIG. 1 includes two semiconductor modules 2.

FIG. 1 illustrates: the semiconductor device 1; a substrate 3 on which the semiconductor device 1 is mounted; and a cooler 4 that cools the semiconductor device 1. The substrate 3 is a circuit board on which a circuit is mounted. For example, a control circuitry that controls the semiconductor device 1 is mounted on the substrate 3. In the example shown in FIG. 1, the cooler 4 is fixed to the semiconductor device 1 by two screws 5. The cooler 4 may have any desired configuration. A radiator may be used as the cooler 4 that cools the semiconductor device 1. Note that, in the following description, a side on which the substrate 3 is disposed with respect to the semiconductor device 1 is referred to as “upper side”, and a side on which the cooler 4 is disposed with respect to the semiconductor device 1 is referred to as “lower side”. The expressions “upper side” and “lower side” are used for convenience, and do not refer to the upper side and lower side of actual placement of the semiconductor device 1.

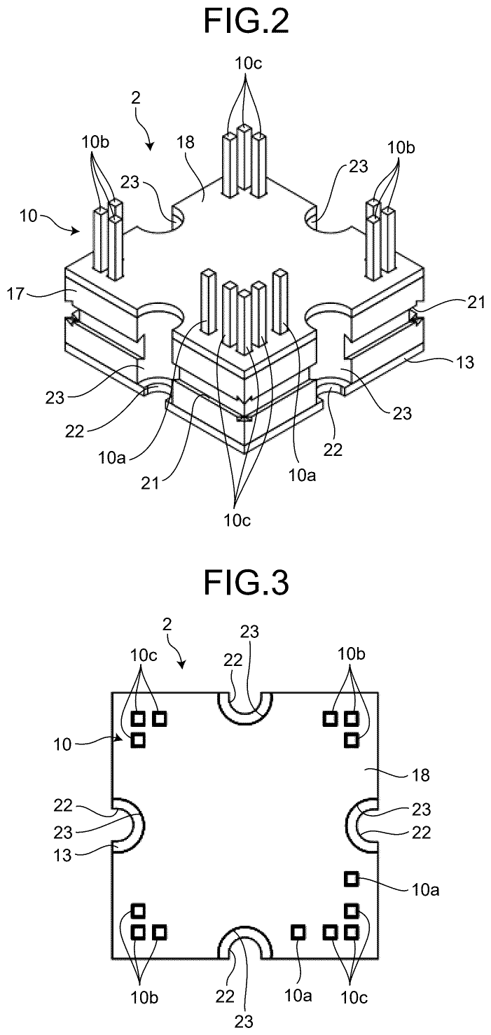

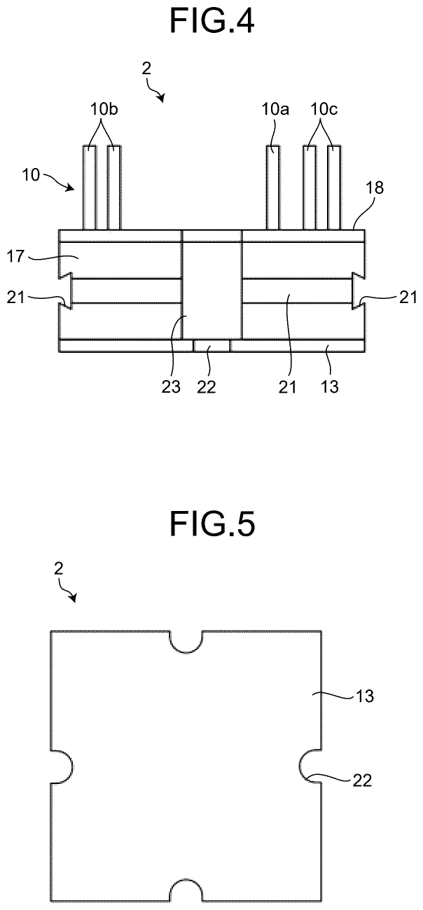

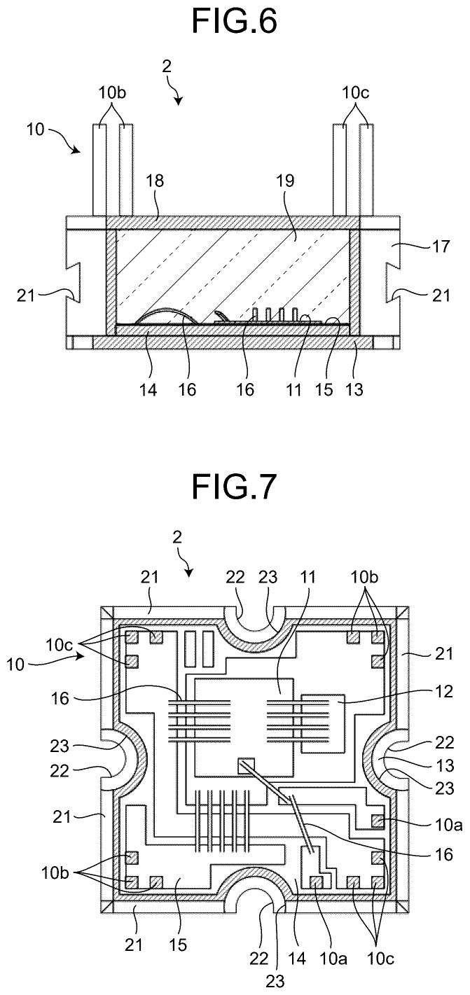

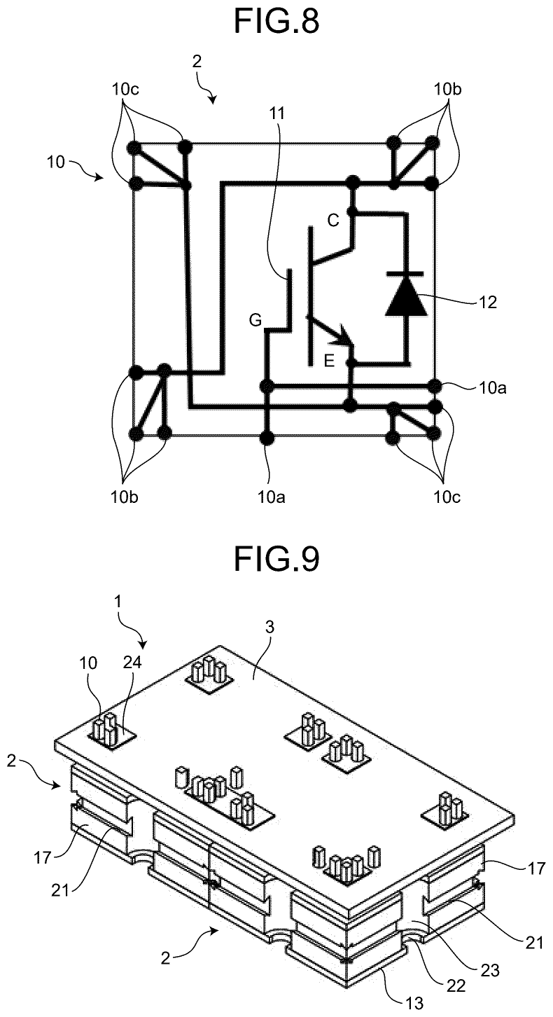

FIG. 2 is a perspective view of the semiconductor module 2 included in the semiconductor device 1 according to the first embodiment. FIG. 3 is a top view of the semiconductor module 2 included in the semiconductor device 1 according to the first embodiment. FIG. 4 is a side view of the semiconductor module 2 included in the semiconductor device 1 according to the first embodiment. FIG. 5 is a bottom view of the semiconductor module 2 included in the semiconductor device 1 according to the first embodiment. FIG. 6 is a longitudinal sectional view of the semiconductor module 2 included in the semiconductor device 1 according to the first embodiment. FIG. 7 is a transverse sectional view of the semiconductor module 2 included in the semiconductor device 1 according to the first embodiment. FIG. 8 is an internal connection diagram of the semiconductor module 2 included in the semiconductor device 1 according to the first embodiment.

As illustrated in FIGS. 6 and 7, the semiconductor module 2 includes: a plurality of main electrodes 10; an insulated gate bipolar transistor (IGBT) 11; a freewheeling diode (FWD) 12; a base plate 13; an insulated substrate 14; a plurality of wires 16; a case 17; a lid 18; and a sealing material 19.

The base plate 13 is a metal plate. The base plate 13 transfers heat generated in each of the IGBT 11 and the FWD 12 to the cooler 4. The material of the base plate 13 is a metal material having high thermal conductivity. Examples of the material of the base plate 13 include copper and aluminum. The base plate 13 has a lower surface and an upper surface. The lower surface is referred to as a first surface. The upper surface is referred to as a second surface that is on a side opposite to the first surface. The lower surface of the base plate 13 is a surface exposed to the outside of the semiconductor module 2 and directed toward the side on which the cooler 4 is disposed. When the lower surface is brought into direct or indirect contact with the cooler 4, the base plate 13 can transfer, to the cooler 4, the heat generated as described above.

The insulated substrate 14 is disposed on an upper surface side of the base plate 13. Examples of insulating material included in the insulated substrate 14 include ceramics and resin. A circuit pattern 15 made of copper foil is provided on the upper surface of the insulated substrate 14.

Each of the IGBT 11 and the FWD 12 is a semiconductor chip bonded to the circuit pattern 15. Each of the IGBT 11 and the FWD 12 is bonded to the circuit pattern 15 by, for example, soldering. The IGBT 11 and the FWD 12 are connected in parallel to each other.

The plurality of wires 16 included in the semiconductor module 2 include: a wire 16 that connects an electrode of the IGBT 11 and an electrode of the FWD 12; a wire 16 that connects an electrode of the IGBT 11 and the circuit pattern 15; and a wire 16 that connects an electrode of the FWD 12 and the circuit pattern 15.

The case 17 is provided on the upper surface of the base plate 13. The case 17 forms a contour of the semiconductor module 2. The case 17 has four side surfaces along an outer edge of the base plate 13. Each of the four side surfaces includes a normal direction of the upper surface of the base plate 13. In the following description, the normal direction of the upper surface of the base plate 13 is simply referred to as a normal direction. FIG. 4 illustrates one of the four side surfaces of the case 17.

The case 17 surrounds: the insulated substrate 14: and the IGBT 11, the FWD 12, the circuit pattern 15, and the plurality of wires 16 on the insulated substrate 14. A lower end portion of the case 17 is closed by the base plate 13. An upper end portion of the case 17 is closed by the lid 18. A space enclosed by the base plate 13, the case 17, and the lid 18 is filled with the sealing material 19. The case 17, the lid 18, and the sealing material 19 are provided on the upper surface side of the base plate 13, and forms a sealer that seals the insulated substrate 14 and the semiconductor chips.

A groove 21 is formed on each of the four side surfaces of the case 17. The groove 21 is recessed from the outside of the sealer toward the inside of the sealer, and extends along a direction perpendicular to the normal direction. A depth direction of the groove 21 is a direction from the outside of the sealer toward the inside of the sealer. A direction in which the groove 21 extends is a direction perpendicular to the normal direction and perpendicular to the depth direction of the groove 21. In the following description, the direction in which the groove 21 extends is also referred to as a longitudinal direction of the groove 21.

The cross section illustrated in FIG. 6 is a cross section including the normal direction, and is a cross section perpendicular to the longitudinal direction of the groove 21 formed on each of two side surfaces facing each other among the four side surfaces. In the cross section illustrated in FIG. 6, the groove 21 has a trapezoidal shape in which the width of the groove 21, which is the length in the normal direction perpendicular to the longitudinal direction, is larger on the inner side of the sealer than on the outer side of the sealer.

One of the two semiconductor modules 2 adjacent to each other illustrated in FIG. 1 is referred to as a first semiconductor module, and the other is referred to as a second semiconductor module. The first semiconductor module and the second semiconductor module are disposed such that one side surface of the first semiconductor module and one side surface of the second semiconductor module face each other. As illustrated in FIG. 1, a pin 6 is inserted into a gap formed by the groove 21 on the one side surface of the first semiconductor module combined with the groove 21 on the one side surface of the second semiconductor module. The pin 6 is inserted along the longitudinal direction of these grooves 21. The first semiconductor module and the second semiconductor module are coupled to each other by the pin 6 inserted in the gap formed by the groove 21 of the first semiconductor module combined with the groove 21 of the second semiconductor module.

When the pin 6 is inserted, a part of the pin 6 is inserted into the groove 21 of the first semiconductor module, and another part of the pin 6 is inserted into the groove 21 of the second semiconductor module. The cross section of the part of the pin 6 to be inserted into the groove 21 of the first semiconductor module and the cross section of the part of the pin 6 to be inserted into the groove 21 of the second semiconductor module each have a trapezoidal shape such that the pin 6 can be fitted into the grooves 21. In a state where the pin 6 is inserted in the grooves 21, the pin 6 does not come off the grooves 21 even if the pin 6 is pulled in a direction perpendicular to the longitudinal direction of the grooves 21. Even when a force is applied to at least one of the first semiconductor module and the second semiconductor module in a direction in which the first semiconductor module and the second semiconductor module are separated from each other, the first semiconductor module and the second semiconductor module are not separated because the pin 6 does not come off the grooves 21. In this manner, the first semiconductor module and the second semiconductor module are coupled to each other by the pin 6. The first semiconductor module and the second semiconductor module are integrated by means of the pin 6.

Note that an example has been described above in which the pin 6 is inserted into the groove 21 on a side surface of the first semiconductor module and the groove 21 on a side surface of the second semiconductor module facing the side surface of the first semiconductor module. Alternatively, the pin 6 may be inserted into the groove 21 on a side surface of the first semiconductor module and the groove 21 on a side surface of the second semiconductor module adjacent to the side surface of the first semiconductor module. In this case, the pin 6 is disposed in such a way as to extend across the first semiconductor module and the second semiconductor module in a direction in which the pin 6 is inserted. Also in this case, the first semiconductor module and the second semiconductor module are integrated by means of the pin 6. The number of pins 6 to be used for coupling the first semiconductor module to the second semiconductor module is not limited to one, and a plurality of pins 6 may be used. The pin 6 just needs to be inserted into the groove 21 of the first semiconductor module and the groove 21 of the second semiconductor module, and the position of insertion of the pin 6 is not limited to a specific position. Furthermore, the shape of the groove 21 is not limited to the trapezoidal shape. The groove 21 just needs to be formed such that the inserted pin 6 does not come off the groove 21 when a force is applied to at least one of the first semiconductor module and the second semiconductor module in the direction in which the first semiconductor module and the second semiconductor module are separated from each other. For example, the groove 21 may have a shape such as an L-shape or an S-shape, and the pin 6 just needs to have a shape corresponding to the groove 21 so that the pin 6 can be inserted into the groove 21.

As illustrated in FIG. 5, four semicircular cutouts 22 are formed in the outer edge of the base plate 13. The planar shape of the base plate 13 is a square with the four cutouts 22 formed therein. The cutout 22 is formed at a midpoint of each side of the square.

The screw 5 illustrated in FIG. 1 is passed through the cutout 22, and is screwed into a hole in the cooler 4. The base plate 13 is fastened to the cooler 4 by the screw 5 screwed into the hole. As a result of the fastening of the base plate 13 to the cooler 4, the semiconductor module 2 is fixed to the cooler 4.

A recess 23 is formed on each of the four side surfaces of the case 17. The recess 23 is formed above the cutout 22. The recess 23 is recessed from the outside of the sealer toward the inside of the sealer, and is formed along the normal direction. The cross section illustrated in FIG. 7 is a cross section perpendicular to the normal direction and passing through the groove 21 formed on each of the four side surfaces of the case 17. In the cross section illustrated in FIG. 7, the recess 23 has a semicircular shape slightly larger than the cutout 22. The depth of the recess 23 corresponds to a length of the recess 23 in the direction from the outside of the sealer toward the inside of the sealer. The depth of the recess 23 is set such that a head of the screw 5 can be passed through the recess 23 when the screw 5 is attached.

In the example shown in FIG. 1, the screws 5 are attached at two positions, that is, the cutout 22 at one end and the cutout 22 at the other end in the direction of arrangement of the first semiconductor module and the second semiconductor module. The first semiconductor module and the second semiconductor module integrated with each other by the pin 6 are fixed to the cooler 4 by the two screws 5. As a result, the cooler 4 is fixed to the semiconductor device 1.

Note that the position where the screw 5 is attached is not limited to the example shown in FIG. 1. In addition, the number of screws 5 to be attached is not limited to two, and may be freely set. The screw 5 just needs to be attached at, at least one of positions where the screw 5 can be attached. Note that a hole into which the screw 5 is screwed is formed at a position where the screw 5 is attached, on the cooler 4.

In the example shown in FIG. 1, there are six cutouts 22 in the outer edge of the planar shape of the semiconductor device 1 when the semiconductor device 1 is viewed from above. The screw 5 can be attached at each position of the six cutouts 22. Furthermore, at the center of the semiconductor device 1 viewed from above, there is a single hole formed by the cutout 22 of the first semiconductor module combined with the cutout 22 of the second semiconductor module. The screw 5 can also be attached at the position of the hole. The screw 5 is attached at, at least one of these positions.

Note that, in a case where the pin 6 is inserted in such a way as to pass through the center of the semiconductor device 1 as illustrated in FIG. 1 and the screw 5 is attached in the hole located at the center of the semiconductor device 1, the pin 6 is inserted after the screw 5 is attached. Alternatively, the pin 6 is inserted into each of the groove 21 of the first semiconductor module and the groove 21 of the second semiconductor module, except for a part corresponding to the recess 23 through which the screw 5 is passed. This prevents the pin 6 from hindering attachment of the screw 5.

According to the above description, the plurality of semiconductor modules 2 of the semiconductor device 1 are integrated by the pin 6 and fixed to the cooler 4 by the screws 5. Thus, the cooler 4 is fixed to the semiconductor device 1. By using the screw 5 and the pin 6 as parts for fixing the cooler 4, it is possible to fix the cooler 4 to the semiconductor device 1 with a small number of parts. Therefore, the structure including the semiconductor device 1 and the cooler 4 can be downsized. In addition, the structure including the semiconductor device 1 and the cooler 4 can be easily assembled. Since the four cutouts 22 are formed in the base plate 13, it is possible to fix the cooler 4 by appropriately choosing the position of the screw 5.

FIG. 3 illustrates the shape of the upper surface of the semiconductor module 2. FIG. 5 illustrates the shape of the lower surface of the semiconductor module 2. The outer edge of the upper surface of the semiconductor module 2 and the outer edge of the lower surface of the semiconductor module 2 have the same shape. A planar shape that is each of the outer edge shape of the upper surface of the semiconductor module 2 and the outer edge shape of the lower surface of the semiconductor module 2 corresponds to the planar shape of the semiconductor module 2 viewed from the normal direction.

When the planar shape of the semiconductor module 2 is rotated at 90 degrees around the center of the planar shape of the semiconductor module 2, the rotated planar shape of the semiconductor module 2 overlaps the planar shape of the semiconductor module 2 yet to be rotated. That is, the planar shape of the semiconductor module 2 has four-fold rotational symmetry. As described above, the planar shape of the semiconductor module 2 is rotationally symmetric. There is no apparent difference in the position and orientation of the contour of the semiconductor module 2 between before and after the semiconductor module 2 is rotated at 90 degrees around an axis extending in the normal direction passing through the center of the planar shape of the semiconductor module 2.

The planar shape of the semiconductor module 2 is identical to the planar shape of the base plate 13, and is a square with the four cutouts 22 formed therein. Since the cutout 22 is formed at the midpoint of each side of the square, the planar shape of the semiconductor module 2 has four-fold rotational symmetry. In addition, the planar shape of the semiconductor module 2 has four corners as with the square.

Here, a first corner is defined as one of the four corners located at a lower left portion of the semiconductor module 2. In the planar shape of the semiconductor module 2, a second corner is defined as a corner on the same diagonal line as the first corner. The second corner is an upper right corner of the semiconductor module 2. That is, the first corner and the second corner are two of the four corners, facing each other across the center of the planar shape of the semiconductor module 2. Furthermore, two of the four corners other than the first corner and the second corner are referred to as a third corner and a fourth corner. The third corner is an upper left corner of the semiconductor module 2. The fourth corner is a lower right corner of the semiconductor module 2. Note that, in the description of FIG. 3, the expressions “upper left”, “lower left”, “upper right”, and “lower right” represent positions with respect to the center of the planar shape of the semiconductor module 2, and represent positions in FIG. 3.

As illustrated in FIG. 8, the plurality of main electrodes 10 included in the semiconductor module 2 includes two gate electrodes 10a, six collector electrodes 10b, and six emitter electrodes 10c. The two gate electrodes 10a, the six collector electrodes 10b, and the six emitter electrodes 10c are collectively referred to as the main electrodes 10 without distinction. In addition, each of the six collector electrodes 10b is also referred to as a first main electrode. Each of the six emitter electrodes 10c is also referred to as a second main electrode.

One end of each of the plurality of main electrodes 10 is soldered to the circuit pattern 15. Each of the plurality of main electrodes 10 is electrically insulated from the base plate 13 by the insulated substrate 14. Another end of each of the plurality of main electrodes 10 is exposed to the outside of the sealer. Each of the plurality of main electrodes 10 penetrates the lid 18, and is drawn out of the sealer to the outside of the sealer. Each of the plurality of main electrodes 10 is drawn out of the sealer in a direction opposite to a direction from the sealer toward the base plate 13, that is, upward. Each of the plurality of main electrodes 10 extends in the normal direction from the surface of the sealer on a side opposite to the base plate 13, that is, from the upper surface of the lid 18.

As illustrated in FIG. 3, three collector electrodes 10b, which are first main electrodes, are drawn out of the first corner. Three collector electrodes 10b, which are first main electrodes, are drawn out of the second corner. Three emitter electrodes 10c, which are second main electrodes, are drawn out of the third corner. Three emitter electrodes 10c, which are second main electrodes, are drawn out of the fourth corner. Furthermore, the two gate electrodes 10a are drawn out at positions adjacent to the three emitter electrodes 10c at the fourth corner.

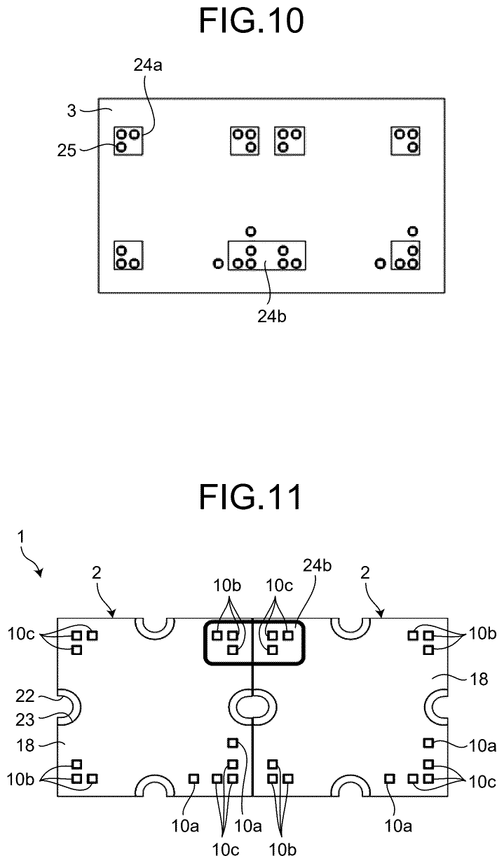

FIG. 9 is a perspective view of the semiconductor device 1 according to the first embodiment, which illustrates a state in which the semiconductor device 1 is mounted on the substrate 3. FIG. 10 is a plan view of the substrate 3 on which the semiconductor device 1 according to the first embodiment is mounted.

As illustrated in FIG. 10, a plurality of holes 25 are formed in the substrate 3. The main electrode 10 is passed through each of the plurality of holes 25. In addition, a plurality of electrodes 24 are provided on the substrate 3. Each of the plurality of electrodes 24 is formed at a position at which the main electrode 10 is passed through the substrate 3. The plurality of electrodes 24 provided on the substrate 3 include: an electrode 24a to which only the main electrode 10 of one of the two semiconductor modules 2 is connected; and an electrode 24b to which the main electrodes 10 of both the two semiconductor modules 2 are connected. The electrode 24b electrically connects the main electrode 10 of one of the two semiconductor modules 2 and the main electrode 10 of the other semiconductor module 2. The electrode 24a and the electrode 24b are collectively referred to as the electrodes 24 without distinction.

The substrate 3 is placed on the semiconductor device 1. The main electrode 10 passed through the hole 25 is connected to the electrode 24 by soldering. As a result, the semiconductor device 1 is mounted on the substrate 3 as illustrated in FIG. 9. The two semiconductor modules 2 are electrically connected to each other via a circuit mounted on the substrate 3.

Since each of the plurality of main electrodes 10 extends in the normal direction from the upper surface of the lid 18, the main electrode 10 can be passed through each hole 25 when the substrate 3 is placed on the semiconductor device 1. Since each main electrode 10 is directly bonded to the substrate 3 by soldering, an additional element for mounting the semiconductor device 1 on the substrate 3, such as wiring or a terminal block, is not necessary. The electrode 24 and the hole 25 just need to be formed on the substrate 3, and there is no need to add, to the substrate 3, an element different from an element to be used in a case where a conventional power module is mounted. Therefore, the semiconductor device 1 can be easily mounted on the substrate 3.

Since the insulated substrate 14 is provided on the semiconductor module 2, each of the plurality of main electrodes 10 and the circuit pattern 15 are electrically insulated from the base plate 13. Since each of the plurality of main electrodes 10 extends upward from the upper surface of the lid 18, electrical insulation of each of the plurality of main electrodes 10 from the cooler 4 can be easily ensured. Therefore, the design of insulation of the semiconductor device 1 can be simplified.

Since the semiconductor modules 2 are disposed such that the main electrode 10 of one of the semiconductor modules 2 and the main electrode 10 of the other semiconductor module 2 are adjacent to each other, the two semiconductor modules 2 can be electrically connected in various layouts by a short wiring pattern. That is, the two semiconductor modules 2 can be electrically connected by a wiring pattern having a small inductance. Since the two semiconductor modules 2 can be electrically connected by a short wiring pattern, a snubber circuit for protection against noise, a protection circuit, or the like can be easily mounted. The fact that the two semiconductor modules 2 can be electrically connected by a short wiring pattern is also advantageous in terms of ease of design and less malfunction. It can be said that the semiconductor device 1 is advantageous from the viewpoints of a high degree of freedom of arrangement of the semiconductor modules 2, simplification of insulation design, simplification of the wiring pattern, downsizing of the circuit, and a small inductance as compared with a case where a conventionally known discrete semiconductor is used.

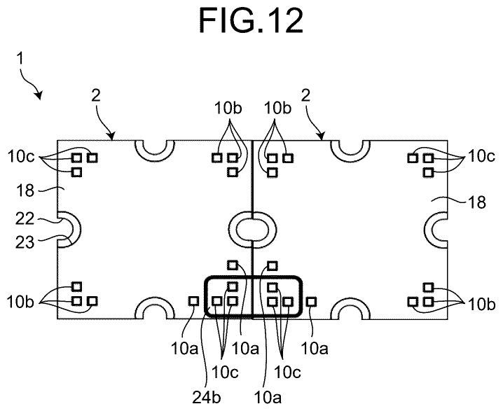

Next, patterns of combination of the semiconductor modules 2 will be described. Here, two exemplary patterns of combination will be described. FIG. 11 is a diagram illustrating a first exemplary pattern of combination of the semiconductor modules 2 in the first embodiment. FIG. 12 is a diagram illustrating a second exemplary pattern of combination of the semiconductor modules 2 in the first embodiment. FIGS. 11 and 12 illustrate the upper surface of the semiconductor device 1 including two semiconductor modules 2.

Of the two semiconductor modules 2, the semiconductor module 2 on the left side is referred to as a first semiconductor module, and the semiconductor module 2 on the right side is referred to as a second semiconductor module, in each of FIGS. 11 and 12. In addition, FIGS. 11 and 12 illustrate the electrode 24b for reference so as to illustrate the main electrodes 10 of the first semiconductor module and the main electrodes 10 of the second semiconductor module electrically connected to each other by the electrode 24b of the substrate 3.

The first exemplary pattern of combination illustrated in FIG. 11 is an example in which the positions of the collector electrodes 10b and the emitter electrodes 10c in the first semiconductor module are the same as the positions of the collector electrodes 10b and the emitter electrodes 10c in the second semiconductor module. In FIG. 11, the collector electrodes 10b are disposed on each of the lower left part and the upper right part of the first semiconductor module, and the emitter electrodes 10c are disposed on each of the upper left part and the lower right part of the first semiconductor module. The arrangement of the collector electrodes 10b and the emitter electrodes 10c on the second semiconductor module is the same as that on the first semiconductor module. In the first exemplary pattern of combination, the first semiconductor module and the second semiconductor module are disposed such that the collector electrodes 10b and the emitter electrodes 10c, which are the main electrodes 10 of different types, are adjacent to each other.

In the first exemplary pattern of combination illustrated in FIG. 11, the collector electrodes 10b on the upper right part of the first semiconductor module and the emitter electrodes 10c on the upper left part of the second semiconductor module are connected to each other by the electrode 24b. In the first exemplary pattern of combination, the first semiconductor module and the second semiconductor module are connected in series. Note that, in the description of FIG. 11, the expressions “upper left”, “lower left”, “upper right”, and “lower right” represent positions with respect to the center of the planar shape of the semiconductor module 2, and represent positions in FIG. 11.

In the second exemplary pattern of combination illustrated in FIG. 12, the second semiconductor module is rotated clockwise at 90 degrees from the state illustrated in FIG. 11. The positions of the collector electrodes 10b and the emitter electrodes 10c on the first semiconductor module in FIG. 12 are the same as those on the first semiconductor module illustrated in FIG. 11. In FIG. 12, the collector electrodes 10b are disposed on each of the upper left part and the lower right part of the second semiconductor module, and the emitter electrodes 10c are disposed on each of the lower left part and the upper right part of the second semiconductor module. In the second exemplary pattern of combination, the first semiconductor module and the second semiconductor module are disposed such that the main electrodes 10 of the same type are adjacent to each other. That is, the collector electrodes 10b as the main electrodes 10 of the same type are adjacent to each other, and the emitter electrodes 10c as the main electrodes 10 of the same type are adjacent to each other.

In the second exemplary pattern of combination illustrated in FIG. 12, the emitter electrodes 10c on the lower right part of the first semiconductor module and the emitter electrodes 10c on the lower left part of the second semiconductor module are connected to each other by the electrode 24b. In the second exemplary pattern of combination, the first semiconductor module and the second semiconductor module are connected in parallel. Note that, in the description of FIG. 12, the expressions “upper left”, “lower left”, “upper right”, and “lower right” represent positions with respect to the center of the planar shape of the semiconductor module 2, and represent positions in FIG. 12. Note that the patterns of combination of the semiconductor modules 2 are not limited to those exemplified in FIGS. 11 and 12.

Since the planar shape of the semiconductor module 2 is rotationally symmetric, there is no apparent difference in the position and orientation of the contour of the second semiconductor module between before and after rotation of the second semiconductor module. In addition, since the collector electrodes 10b are disposed at two corners on one diagonal line and the emitter electrodes 10c are disposed at two corners on the other diagonal line, the positions of the collector electrodes 10b and the emitter electrodes 10c on the second semiconductor module are different between FIGS. 11 and 12.

As exemplified in FIGS. 11 and 12, the semiconductor device 1 can change the way of arrangement of the first main electrodes and the second main electrodes on each semiconductor module 2 without changing the position and orientation of the contour of the semiconductor module 2. Therefore, each of the semiconductor modules 2 coupled to each other can be disposed with a high degree of freedom. In addition, electric connection between the main electrodes 10 of the semiconductor modules 2 can be chosen with a high degree of freedom.

In the semiconductor device 1, by appropriately disposing the electrodes 24b, it is possible to choose the way of electric connection between the semiconductor modules 2 coupled to each other, with a high degree of freedom. For example, the electric connection between the semiconductor modules 2 can be freely chosen between series connection and parallel connection. The semiconductor modules 2 connected in series with each other and the semiconductor modules 2 connected in parallel to each other may be mixed in the semiconductor device 1.

Note that, in the above description, each main electrode 10 is electrically connected to the substrate 3 by soldering, but a method other than soldering may be used for connecting each main electrode 10 to the substrate 3. For example, each main electrode 10 may be press-fitted into the substrate 3 to be electrically connected to the substrate 3.

In the above description, the sealer of the semiconductor module 2 includes the case 17, the lid 18, and the sealing material 19. The configuration of the sealer is not limited to the configuration described above. The sealer may be formed of, for example, molding resin. The constituent elements provided on the upper surface of the base plate 13 are sealed by being covered with molding resin. The molding resin may be a transfer mold formed by transfer molding.

The semiconductor chip provided in the semiconductor module 2 may be a semiconductor chip other than the IGBT 11 and the FWD 12. The semiconductor chip included in the semiconductor module 2 may be, for example, a metal oxide semiconductor field-effect transistor (MOSFET), a diode, a silicon carbide (SiC) device, or a gallium nitride (GaN) device. For example, when the semiconductor chip included in the semiconductor module 2 is a MOSFET, a source electrode and a drain electrode may serve as the first main electrode and the second main electrode described above, respectively. When the semiconductor chip included in the semiconductor module 2 is a diode, an anode electrode and a cathode electrode may serve as the first main electrode and the second main electrode described above, respectively. The semiconductor module 2 may be an intelligent power module (IPM) in which a gate drive circuit is added to the constituent elements to be sealed in the sealer.

In the above description, the semiconductor device 1 includes two semiconductor modules 2. The number of semiconductor modules 2 to be included in the semiconductor device 1 may be freely set. In addition, the way of arrangement of the plurality of semiconductor modules 2 may also be freely chosen. The way of arrangement of the plurality of semiconductor modules 2 may be determined in accordance with the configuration of an electric apparatus including the semiconductor device 1. For example, the way of arrangement of the plurality of semiconductor modules 2 may be determined in accordance with the circuit type of a power converter including the semiconductor device 1.

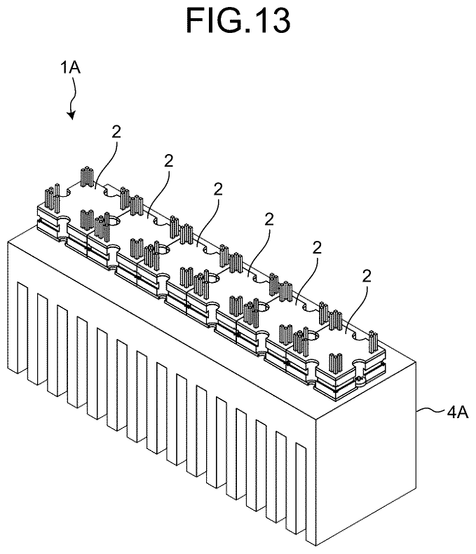

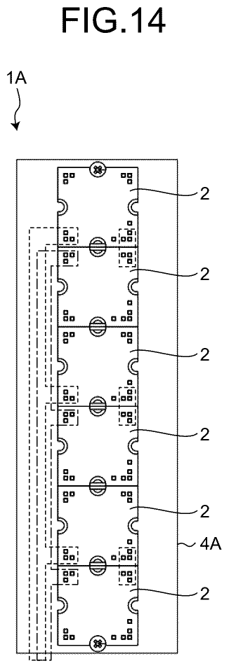

Next, modifications of the semiconductor device 1 will be described. FIG. 13 is a perspective view of a semiconductor device 1A according to a first modification of the first embodiment. FIG. 14 is a top view of the semiconductor device 1A according to the first modification of the first embodiment. FIGS. 13 and 14 illustrate the semiconductor device 1A and a heat sink 4A serving as a cooler. The heat sink 4A is fixed to the semiconductor device 1A.

The semiconductor device 1A includes six semiconductor modules 2 arranged in line in accordance with the shape of the heat sink 4A. In FIG. 14, an example of connection by the front-side wiring of the substrate 3 is indicated by alternate long and short dash lines, and an example of connection by the back-side wiring of the substrate 3 is indicated by broken lines. The six semiconductor modules 2 include the semiconductor modules 2 adjacent to each other and connected to each other by the substrate 3. Furthermore, among the six semiconductor modules 2, the semiconductor modules 2 that are not adjacent to each other may be connected to each other by the substrate 3 as illustrated in FIG. 14. For example, a configuration in which a plurality of semiconductor modules 2 is arranged in line as in the semiconductor device 1A can be applied to a slim electric apparatus. As described above, it is possible to implement the semiconductor device 1A in which the plurality of semiconductor modules 2 is arranged in such a way as to match a desired shape of the electric apparatus.

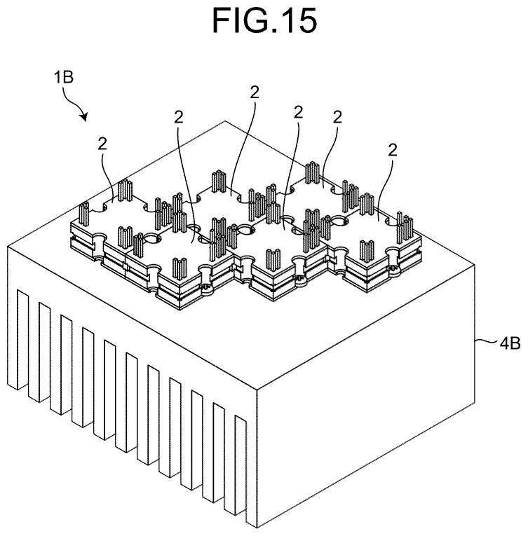

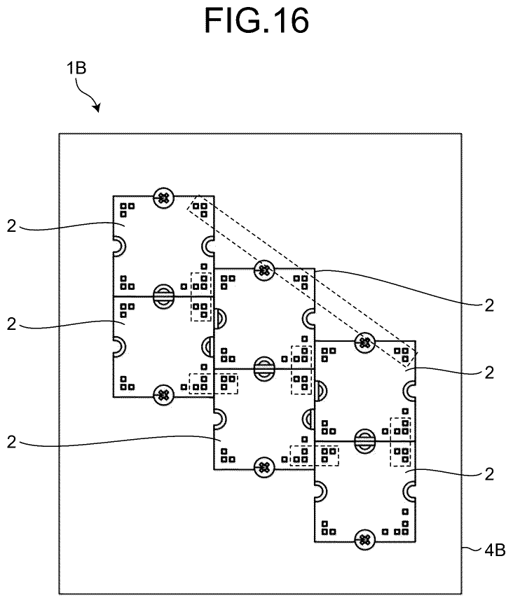

FIG. 15 is a perspective view of a semiconductor device 1B according to a second modification of the first embodiment. FIG. 16 is a top view of the semiconductor device 1B according to the second modification of the first embodiment. FIGS. 15 and 16 illustrate the semiconductor device 1B and a heat sink 4B serving as a cooler. The heat sink 4B is fixed to the semiconductor device 1B.

The semiconductor device 1B includes three sets of two semiconductor modules similar to the two semiconductor modules 2 illustrated in FIG. 1. That is, the semiconductor device 1B includes six semiconductor modules 2. The six semiconductor modules 2 are arranged in a staggered arrangement. In FIG. 16, an example of connection by the wiring of the substrate 3 is indicated by broken lines.

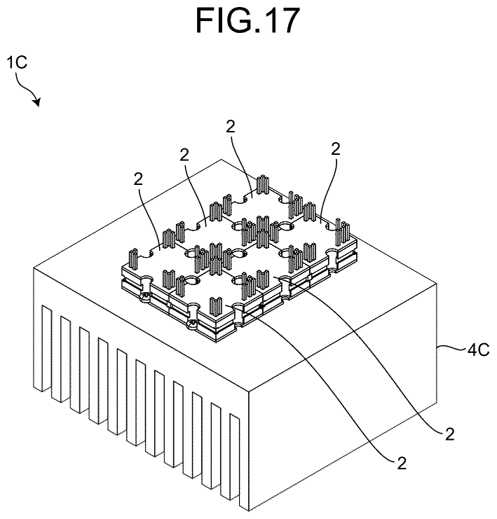

FIG. 17 is a perspective view of a semiconductor device 1C according to a third modification of the first embodiment. FIG. 17 illustrates the semiconductor device 1C and a heat sink 4C serving as a cooler. The heat sink 4C is fixed to the semiconductor device 1C. The semiconductor device 1C includes three sets of two semiconductor modules similar to the two semiconductor modules 2 illustrated in FIG. 1. That is, the semiconductor device 1C includes six semiconductor modules 2. The six semiconductor modules 2 are arranged in a matrix.

The plurality of semiconductor modules 2 of the semiconductor device 1 may be arranged in a staggered arrangement as illustrated in FIGS. 15 and 16, or may be arranged in a matrix as illustrated in FIG. 17. The semiconductor modules 2 arranged in a staggered arrangement and the semiconductor modules 2 arranged in a matrix may be mixed in the plurality of semiconductor modules 2 of the semiconductor device 1.

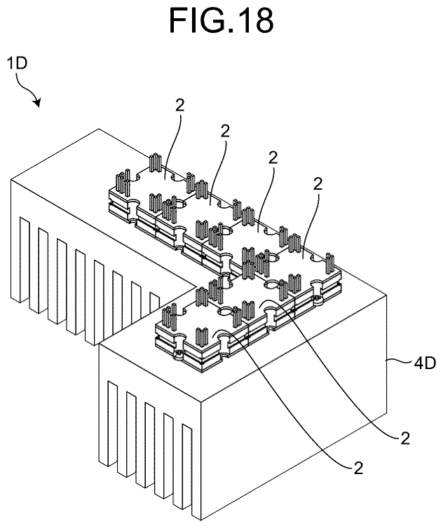

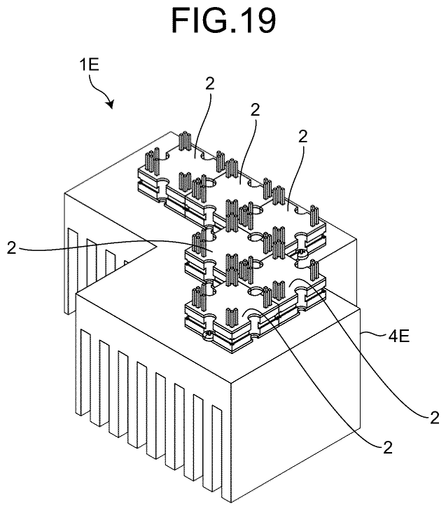

FIG. 18 is a perspective view of a semiconductor device 1D according to a fourth modification of the first embodiment. FIG. 18 illustrates the semiconductor device 1D and a heat sink 4D serving as a cooler. The heat sink 4D is fixed to the semiconductor device 1D. The semiconductor device 1D includes six semiconductor modules 2. The heat sink 4D has an L-shape in plan view. The six semiconductor modules 2 are arranged in an L-shape so as to match the planar shape of the heat sink 4D. For example, arrangement of the plurality of semiconductor modules 2 may be determined as in the semiconductor device 1D, in accordance with the shape of an electric apparatus intended by a designer. As described above, it is possible to implement the semiconductor device 1D in which the plurality of semiconductor modules 2 is arranged in such a way as to match a desired shape of the electric apparatus.

FIG. 19 is a perspective view of a semiconductor device 1E according to a fifth modification of the first embodiment. FIG. 19 illustrates the semiconductor device 1E and a heat sink 4E serving as a cooler. The heat sink 4E is fixed to the semiconductor device 1E. The semiconductor device 1E includes six semiconductor modules 2. The six semiconductor modules 2 are arranged in such a way as to match the planar shape of the heat sink 4E. The arrangement illustrated in FIG. 17 or the arrangement illustrated in FIG. 18 has been further modified to obtain arrangement of the six semiconductor modules 2 in FIG. 19.

For example, the arrangement of the plurality of semiconductor modules 2 may be determined as in the semiconductor device 1E, in accordance with the shape of the electric apparatus intended by the designer. As described above, it is possible to implement the semiconductor device 1E in which the plurality of semiconductor modules 2 is arranged in such a way as to match a desired shape of the electric apparatus.

It is possible to implement the semiconductor devices 1A to 1E with a configuration matching the intention of the designer by arranging the plurality of semiconductor modules 2 as in the modifications of the first embodiment. As a result, the semiconductor devices 1A to 1E can be applied to power converters of various circuit types, such as a three-phase inverter, a single-phase inverter, a chopper, and a three-level inverter. The semiconductor devices 1A to 1E can also implement a function equivalent to that of a power module in which a plurality of semiconductor chips is mounted in a single package, by combining a plurality of semiconductor modules 2.

When a failure occurs in the plurality of semiconductor modules 2 in the semiconductor devices 1 and 1A to 1E described in the first embodiment, only the failed semiconductor module 2 can be replaced. Therefore, according to the first embodiment, it is possible to reduce the repair cost of the semiconductor devices 1 and 1A to 1E.

According to the first embodiment, each of the plurality of semiconductor modules 2 included in the semiconductor devices 1 and 1A to 1E has a planar shape with four corners, and has a rotationally symmetric shape. The first main electrode is drawn out at each of the first corner and the second corner facing each other among the four corners. The second main electrode is drawn out at each of the third corner and the fourth corner which are two of the four corners other than the first corner and the second corner. In the semiconductor module 2 having such a configuration, it is possible to change the way of arrangement of the first main electrode and the second main electrode in the semiconductor module 2 by rotating the semiconductor module 2, without changing the position and orientation of the contour of the semiconductor module 2. In addition, electric connection between the main electrodes 10 of the semiconductor modules 2 can be chosen with a high degree of freedom. As described above, achieved is an effect of enabling each of the plurality of semiconductor modules 2 to be disposed with a high degree of freedom.

The configurations set forth in the above embodiment are examples of the subject matter of the present disclosure. The configurations of the embodiment can be combined with another known technique. It is possible to partially omit or change the configurations of the embodiment without departing from the scope of the present disclosure.

### REFERENCE SIGNS LIST

1, 1A, 1B, 1C, 1D, 1E semiconductor device; 2 semiconductor module; 3 substrate; 4 cooler; 4A, 4B, 4C, 4D, 4E heat sink; 5 screw; 6 pin; 10 main electrode; 10a gate electrode; 10b collector electrode; 10c emitter electrode; 11 IGBT; 12 FWD; 13 base plate; 14 insulated substrate; 15 circuit pattern; 16 wire; 17 case; 18 lid; 19 sealing material; 21 groove; 22 cutout; 23 recess; 24, 24a, 24b electrode; 25 hole.

1. A semiconductor device comprising:
a plurality of semiconductor modules, wherein
each of the plurality of semiconductor modules includes:
a base plate having a first surface and a second surface, the first surface being exposed to an outside of the semiconductor module, the second surface being on a side opposite to the first surface;
an insulated substrate disposed on a side of the second surface, and on which a circuit pattern is provided;
a semiconductor chip bonded to the circuit pattern;
a sealer provided on the side of the second surface, the sealer sealing the insulated substrate and the semiconductor chip; and
a first main electrode and a second main electrode drawn out of the sealer in a direction opposite to the base plate,
when viewed from a normal direction of the second surface, the semiconductor module has a planar shape with four corners, and has a rotationally symmetric shape,
at each of a first corner and a second corner, the first main electrode is drawn out of the sealer, the first corner and the second corner being two of the four corners, the first corner and the second corner facing each other across a center of the planar shape, and
at each of a third corner and a fourth corner, the second main electrode is drawn out of the sealer, the third corner and the fourth corner being two of the four corners other than the first corner and the second corner.

2. The semiconductor device according to claim 1, wherein
the sealer has four side surfaces including the normal direction of the second surface,
a groove is formed on each of the four side surfaces, the groove being recessed toward inside of the sealer, the groove extending along a direction perpendicular to the normal direction of the second surface, and
a first semiconductor module and a second semiconductor module are coupled to each other by a pin inserted in the groove of the first semiconductor module and the groove of the second semiconductor module, the first semiconductor module and the second semiconductor module being two of the semiconductor modules, and being adjacent to each other.

3. The semiconductor device according to claim 1, wherein
a cutout, for passing a screw configured to fix the base plate to a cooler, is formed in an outer edge of the base plate.

4. The semiconductor device according to claim 1, wherein
each of the first main electrode and the second main electrode is electrically insulated from the base plate by the insulated substrate.

5. The semiconductor device according to claim 1, wherein
each of the first main electrode and the second main electrode extends in the normal direction of the second surface from a surface of the sealer, the surface being on a side opposite to the base plate.
